(19) United States
(12) Patent Application Publication
(10) Pub. No.: US 2026/0317353 A1
(43) Pub. Date: Oct. 15, 2026

(54) AG-BASED ORGANIC COORDINATION NANOPARTICLE AND PREPARATION METHOD THEREFOR, AND PHOTORESIST COMPOSITION AND USE THEREOF

(71) Applicants: Beijing Vfortune New Energy Power Technology Development Co., Ltd., Beijing (CN); Tsinghua University, Beijing (CN)

(72) Inventors: Hong Xu, Beijing (CN); Xiangming He, Beijing (CN); Xiaolin Wang, Beijing (CN)

(21) Appl. No.: 18/995,901

(22) PCT Filed: May 14, 2024
(86) PCT No.: PCT/CN2024/093186

§ 371 Date: Jan. 17, 2025

(30) Foreign Application Priority Data
May 18, 2023 (CN) 202310566757.6

(51) Int. Cl. C07F 9/50; B82Y 40/00; G03F 7/004; G03F 7/16; G03F 7/20

(52) U.S. Cl. CPC C07F 9/5045; G03F 7/0042; G03F 7/162; G03F 7/2004; B82Y 40/00

(57) ABSTRACT

The present invention relates to an Ag-based organic coordination nanoparticle and a preparation method therefor, and a photoresist composition and the use thereof. The general formula of the Ag-based organic coordination nanoparticle is [Agₘ(R)ₙ(Q)ₓ]_{y}. The preparation method for the Ag-based organic coordination nanoparticle comprises: separately adding a silver salt and a first organic ligand to a sample bottle, adding an organic solvent thereto to dissolve same, stirring same for a certain period of time under certain temperature conditions, subjecting same to filtration, concentration, and cooling crystallization or evaporative crystallization, and finally, performing recrystallization in an organic solvent, so as to obtain the Ag-based organic coordination nanoparticle. The nanoparticle composition can be used as an electron beam, medium-ultraviolet, deep-ultraviolet or EUV photoresist.

### TECHNICAL FIELD

The invention relates to the technical field of photoresists, and in particular to Ag-based organic coordination nanoparticles and a preparation method therefor, a photoresist composition and use thereof.

### BACKGROUND

Photoresist refers to a corrosion-resistant thin film material whose solubility changes when exposed to Ultra-Violet light, electron beam, ion beam, Extreme Ultra-Violet (EUV) light or soft X-rays. It is widely used in pattern transfer in the manufacturing process of premium micro-nano structures, comprising semiconductor integrated circuits, liquid crystal panel processing, and premium optical device manufacturing. With the continuous advancement of semiconductor technology and the development of Moore's Law, the semiconductor process continues to shrink, and higher requirements have been put forward for the reduction of processing feature size. In order to meet more advanced semiconductor processes and achieve smaller feature sizes, photolithography technology is also continuously developing, from I-line, G-line, Deep Ultra-Violet (DUV) (comprising KrF lithography at 248 nm and ArF lithography at 193 nm) to fine processing means such as Extreme Ultra-Violet lithography, electron beam lithography. After the photoresist film is exposed and developed to form a lithographic pattern, it will be dry or wet etched. The part of the substrate material not covered by the film is directly etched, while the substrate surface covered by the film is protected by the photoresist film and is not etched. Etching resistance is a very important evaluation parameter of photoresist. Excellent etching resistance can ensure that the photoresist can protect the substrate surface from damage during the etching process, effectively simplify the etching process, and greatly improve the yield of the finished etching product.

Extreme Ultra-Violet lithography has attracted attention as a basic technology for manufacturing next-generation semiconductor devices. EUV lithography is a pattern forming technology that uses EUV rays with a wavelength of about 13.5 nanometers as an exposure light source. According to EUV lithography, it is known that extremely fine patterns (for example, less than or equal to about 20 nanometers) can be formed in the exposure process during the manufacture of semiconductor devices. For the exposure under the wavelength of Extreme Ultra-Violet, the absorptivity of the photoresist itself, the reaction mechanism of solubility changes after exposure, and the size distribution of the photoresist components have great influence on the comprehensive performance of the photoresist. Since metal elements have a higher absorptivity to EUV radiation, metal-containing photoresist materials have aroused people's interest, and a photoresist containing a metal oxide nanoparticle is one of the hot research directions. The Ober research group at Cornell University in the United States first introduced the concept of a metal oxide nanoparticle as the next-generation material for Extreme Ultra-Violet photoresists. The synthesis of such a nanoparticle is achieved generally by controlling the hydrolysis of alcohol salts of Zr or Hf in excess carboxylic acid, followed by precipitation treatment, thereby obtaining a photoresist containing a nanoparticle of ZrO₂ or HfO₂ with organic ligand(s), and the size of the corresponding nanoparticles is controlled at 2~5 nm, making it conducive to the lithography below 20 nm. In order to further find a more efficient metal-organic nanophotoresist, the present invention focuses on a photoresist containing an Ag-based organic coordination nanoparticle and prepares a photoresist with excellent lithography performance.

### SUMMARY

### Technical Problem

The problem solved by the embodiments of the present invention is to provide a novel Ag-based organic coordination nanoparticle and a preparation method therefor, a photoresist composition containing the same and use thereof.

### Technical Solution

The present invention provides an Ag-based organic coordination nanoparticle, with a general formula of [Agₘ(R)ₙ(Q)ₓ]_{y},
wherein R may be selected from bis(diphenylphosphine)methane (dppm), bis(dicyclohexylphosphine)methane (abbreviated as dcpm), bis(diphenylamino)methane, N,N-bis(diphenylphosphine)amine (abbreviated as dppa), N,N,N′,N′-tetramethyldiaminomethane, N,N,N′,N′-tetraethyldiaminomethane, etc.;

Q may be selected from CH₃COO, C₂H₅COO, C₃H₇COO, i-C₃H₇COO, C₄H₉COO, C₆H₁₃COO, C₉H₁₉COO, C₆H₅COO, CF₃COO, C₂F₅COO, C₃F₇COO, i-₃F₇COO, C₄F₉COO, C₆F₁₃COO, C₉F₁₉COO and C₆H₅COO, etc. ;
wherein each of m, n, x and y is in the range of 1 to 4.

Furthermore, the Ag-based organic coordination nanoparticle may have the following structure:

Ag₂(dppm)₂(CH₃COO)₂;

Ag₄(dppm)₂(CH₃COO)₄;

Ag₄(dppm)₂(CF₃COO)₄;

Ag₂(dppm)₂(C₂H₅COO)₂;

Ag₄(dppm)₂(C₂F₅COO)₄;

Ag₄(dppm)₂(C₄F₉COO)₄;

Ag₂(dcpm)₂(CH₃COO)₂; and/or

Ag₄ (dppa)₂(CH₃COO)₄.

The size of the Ag-based organic coordination nanoparticle crystal is 1 nm to 4 nm, preferably 1 nm to 2 nm.

The above-mentioned Ag-based organic coordination nanoparticle is prepared by the following method:
adding a silver salt and a first organic ligand to a sample bottle respectively, and adding an organic solvent thereto to dissolve them;
stirring the solution for a certain period under a certain temperature condition;
subjecting the solution to filtration, concentration, and cooling crystallization or evaporative crystallization; and
finally performing recrystallization in an organic solvent to obtain the Ag-based organic coordination nanoparticle.

Further, the ratio of the silver salt to the first organic ligand is 1: (0.5~1).

The organic solvent is any one or more selected from ethyl acetate, butyl acetate, propylene glycol monoethyl ether acetate, propylene glycol methyl ether acetate, 1-ethoxy-2-propanol, tetrahydrofuran, methanol, ethanol, propanol, dichloromethane, and trichloromethane.

The stirring temperature is controlled at 0~120 °C, preferably 15~80 °C, and more preferably 20~40 °C.

The present invention also provides a photoresist composition, comprising the above-mentioned nanoparticle.

Further, the above-mentioned photoresist composition further comprises a photoinitiator and an organic dispersing solvent, the photoinitiator preferably makes up 0.1wt %~10wt % of the composition, and the nanoparticle preferably makes up 1wt %~20wt % of the composition.

Further, the photoinitiator is any one or more selected from N-hydroxynaphthaleneimide trifluoromethanesulfonic acid, 1,4-aminonaphthalenesulfonic acid, 2-amino-5,7-naphthalene disulfonic acid, tert-butylphenyl iodonium perfluorooctanesulfonic acid, triphenylsulfonium perfluorobutanesulfonic acid, triphenylsulfonium perfluorobutyl and triphenylsulfonium trifluorosulfonic acid.

Further, the organic dispersing solvent is any one or more selected from ethyl acetate, butyl acetate, propylene glycol monoethyl ether acetate, propylene glycol methyl ether acetate, 1-methoxy-2-propanol, propylene glycol mono-n-propyl ether, propylene glycol butyl ether, 1-ethoxy-2-propanol, methanol, ethanol and propanol. The solvent is preferably 1-ethoxy-2-propanol.

### Method for Patterning a Photoresist Containing a Metal-Organic Coordination Nanoparticle

The present invention also provides a method for forming a lithographic pattern, using the above-mentioned photoresist composition, dripping the photoresist composition onto a substrate by spin-coating to form a film, heating the substrate on a hot stage, then exposing the substrate under electron beam or Mid-Ultra-Violet, Deep Ultra-Violet, or Extreme Ultra-Violet, and developing the substrate with a developing agent.

Further, the spin-coating speed is from 1000 rpm to 6000 rpm; the heating temperature of the hot stage is controlled at 50~110 °C, and the heating period is controlled within 30~900 s.

Further, the exposure dose is from 50 to 8000 mJ/cm².

Further, the developing agent is any one or any mixture of more selected from decalin, tetralin, indene, indane, quinoline, 1-methylnaphthalene, toluene, o-xylene, m-xylene, p-xylene, ethyl acetate, butyl acetate, ethanol, n-propanol, isopropanol, n-butanol, isobutanol, 1-methoxy-2-propanol, 1-ethoxy-2-propanol, propylene glycol mono-n-propyl ether, propylene glycol butyl ether, n-hexane and cyclohexane, and the developing temperature is room temperature or 20 °C~50 °C.

The thickness of the pre-film layer after removing the organic dispersing solvent may be 10 nm~100 nm. Specifically, the thickness of the pre-film layer may be 10 nm~20 nm, 20 nm~30 nm, 30 nm~40 nm, 40 nm~50 nm, 50 nm~60 nm, 60 nm~70 nm, 70 nm~80 nm, 80 nm~90 nm, or 90 nm~100 nm.

The substrate is selected from a silicon sheet. Other substrates that are insoluble in the developing agent may also be selected according to actual needs.

Furthermore, the present invention provides use of the above nanoparticle in the field of photoresist, in particular photoresists for electron beam, Mid-Ultra-Violet, Deep Ultra-Violet, and EUV. Regarding the mask, a transmission mask is adopted for the Deep Ultra-Violet and longer wavelength light sources, a reflection mask is adopted for the Extreme Ultra-Violet, and the electron beam is used for exposure according to the pattern set by the software.

### Beneficial Effects

Compared with the prior art, the technical solution of the present invention has the following advantages:

The Ag-based organic coordination nanoparticle provided in the embodiment of the present invention has a special structure. The photoacid generator will generate photoacid after being irradiated by ultraviolet light. The photoacid can interact with the Ag-based organic coordination nanoparticle, thereby changing the polarity of the Ag-based organic coordination nanoparticle, causing the nanoparticles to agglomerate. Therefore, the solubility of the Ag-based organic coordination nanoparticle changes before and after exposure. Due to these characteristics, the Ag-based organic coordination nanoparticle may be used as a photoresist component, which can make the solubility of the photosensitive part and the light-shielding part of the photoresist in the developing agent different. The photosensitive part agglomerates in the developing agent, and the solubility thereof is reduced, while the light-shielding part does not agglomerate and dissolves in the developing agent, so that the non-exposed area can be removed after development to obtain a pattern of the desired shape. Using the Ag-based organic coordination nanoparticle of the present invention as a photoresist component can achieve more excellent lithography performance such as high resolution, high sensitivity, and low line roughness.

### BRIEF DESCRIPTION OF THE DRAWINGS

FIG. 1 is the structural formula of the crystalline compound prepared in Example 1 of the present invention;

FIG. 2 is the H-NMR spectrum of the crystalline compound prepared in Example 1 of the present invention;

FIG. 3 is the dynamic light scattering particle size test result of Example 1 of the present invention;

FIG. 4 is the exposure pattern of Example 1 of the present invention;

FIG. 5 is the structural formula of Example 2 of the present invention;

FIG. 6 is the H-NMR spectrum of Example 2 of the present invention;

FIG. 7 is the dynamic light scattering particle size test result of Example 2 of the present invention;

FIG. 8 is the exposure pattern of Example 2 of the present invention;

FIG. 9 is the structure of Example 3 of the present invention;

FIG. 10 is the H-NMR spectrum of Example 3 of the present invention;

FIG. 11 is the dynamic light scattering particle size test result of Example 3 of the present invention;

FIG. 12 is the exposure pattern of Example 3 of the present invention.

### DETAILED DESCRIPTION OF THE PREFERRED EMBODIMENTS

### Embodiments of the Present Invention

In order to facilitate the understanding of the present invention, the present invention will be described more completely below with reference to the relevant drawings. The preferred embodiments of the present invention are shown in the drawings. However, the present invention can be implemented in many different forms and is not limited to the embodiments described herein. On the contrary, the purpose of providing these embodiments is to make the understanding of the disclosure of the present invention more thorough and comprehensive.

Unless otherwise defined, all technical and scientific terms used herein have the same meaning as those generally understood by technicians in the technical field of the present invention. The terms used in the specification of the present invention herein are only for the purpose of describing specific embodiments and are not intended to limit the present invention.

The present invention provides an Ag-based organic coordination nanoparticle, the general formula of which is [Agₘ(R)ₙ(Q)ₓ]_{y};
wherein R may be selected from bis(diphenylphosphine)methane (dppm), bis(dicyclohexylphosphine)methane (abbreviated as dcpm), bis(diphenylamino)methane, N,N-bis(diphenylphosphine)amine (abbreviated as dppa), N,N,N′,N′-tetramethyldiaminomethane, N,N,N′,N′-tetraethyldiaminomethane, etc.;

Q may be selected from CH₃COO, C₂H₅COO, C₃H, COO, i-C₃H₇COO, C₄H₉COO, C₆H₁₃COO, C₉H₁₉CO, C₆H₅COO, CF₃COO, C₂F₅COO, C₃F₇COO, i-C₃F₇COO, C₄F₉COO, C₆F₁₃COO, C₉F₁₉COO and C₆H₅COO, etc. ;
wherein each of m, n, x and y is in the range of 1 to 4.

Furthermore, the Ag-based organic coordination nanoparticle may have the following structure:

Ag₂(dppm)₂(CH₃COO)₂;

Ag₄(dppm)₂(CH₃COO)₄;

Ag₄(dppm)₂(CF₃COO)₄;

Ag₂(dppm)₂(C₂H, COO)₂;

Ag₄(dppm)₂(C₂F₅COO)₄;

Ag₄(dppm)₂(C₄F₉COO)₄;

Ag₂(dcpm)₂(CH₃COO)₂; and/or

Ag₄ (dppa)₂(CH₃COO)₄.

The size of the Ag-based organic coordination nanoparticle crystal is 1 nm to 4 nm, preferably 1 nm to 2 nm.

The Ag-based organic coordination nanoparticle provided in the embodiment of the present invention has a special structure. The photoacid generator generates photoacid after being irradiated by ultraviolet light. The photoacid can interact with the Ag-based organic coordination nanoparticle, thereby changing the polarity of the Ag-based organic coordination nanoparticle, causing the nanoparticles to agglomerate. Therefore, the solubility of the Ag-based organic coordination nanoparticle changes before and after exposure. Due to these characteristics, the Ag-based organic coordination nanoparticle may be used as a photoresist component, which can make the solubility of the photosensitive part and the light-shielding part of the photoresist in the developing agent different. The photosensitive part agglomerates and the solubility thereof in the developing agent is reduced, while the light-shielding part does not agglomerate and dissolves in the developing agent, so that the non-exposed area can be removed after development to obtain a pattern of the desired shape. Using the Ag-based organic coordination nanoparticle of the present invention as a photoresist component can achieve more excellent lithography performance such as high resolution, high sensitivity, and low line roughness.

The above-mentioned Ag-based organic coordination nanoparticle is prepared by the following method:
adding a silver salt and a first organic ligand to a sample bottle respectively, and adding an organic solvent thereto to dissolve them;
stirring the solution for a certain period under a certain temperature condition;
subjecting the solution to filtration, concentration, and cooling crystallization or evaporative crystallization; and
finally performing recrystallization in an organic solvent to obtain the Ag-based organic coordination nanoparticle.

Further, the ratio of the silver salt to the first organic ligand is 1: (0.5~1).

The organic solvent is any one or more selected from ethyl acetate, butyl acetate, propylene glycol monoethyl ether acetate, propylene glycol methyl ether acetate, 1-ethoxy-2-propanol, tetrahydrofuran, methanol, ethanol, propanol, dichloromethane, and trichloromethane.

The stirring temperature is controlled at 0~120 °C, preferably 15~80 °C, and more preferably 20~40 °C.

Some embodiments of the present invention provide a photoresist composition containing an Ag-based organic coordination nanoparticle, comprising the above-mentioned nanoparticle, and also comprising a photoinitiator and an organic dispersing solvent, wherein the photoinitiator preferably makes up 0.1wt %- 10wt % of the composition, and the nanoparticle preferably makes up 1wt %-20% of the composition.

Further, the photoinitiator is any one or more selected from N-hydroxynaphthaleneimide trifluoromethanesulfonic acid, 1,4-aminonaphthalenesulfonic acid, 2-amino-5,7-naphthalene disulfonic acid, tert-butylphenyl iodonium perfluorooctanesulfonic acid, triphenylsulfonium perfluorobutanesulfonic acid, triphenylsulfonium perfluorobutyl and triphenylsulfonium trifluorosulfonic acid.

Further, the organic dispersing solvent is any one or more selected from ethyl acetate, butyl acetate, propylene glycol monoethyl ether acetate, propylene glycol methyl ether acetate, 1-methoxy-2-propanol, propylene glycol mono-n-propyl ether, propylene glycol butyl ether, 1-ethoxy-2-propanol, methanol, ethanol and propanol. The solvent is preferably 1-ethoxy-2-propanol.

Some embodiments of the present invention provide a method for patterning a photoresist comprising an Ag-based organic coordination nanoparticle, using the above-mentioned photoresist composition, dripping the photoresist composition onto a substrate by spin-coating to form a film, heating the substrate on a hot stage, then exposing the substrate under electron beam or Mid-Ultra-Violet, Deep Ultra-Violet, or Extreme Ultra-Violet, and developing the substrate with a developing agent.

Further, the spin-coating speed is from 1000 rpm to 6000 rpm; the heating temperature of the hot stage is controlled at 50~110 °C, and the heating period is controlled within 30~900 s.

Further, the exposure dose is from 50 to 8000 mJ/cm².

Further, the developing agent is any one or any mixture of more selected from decalin, tetralin, indene, indane, quinoline, 1-methylnaphthalene, toluene, o-xylene, m-xylene, ethyl acetate, butyl acetate, ethanol, n-propanol, isopropanol, n-butanol, n-hexane and cyclohexane, and the developing temperature is room temperature or 20 °C~50 °C.

The thickness of the pre-film layer after removing the organic dispersing solvent may be 10 nm~100 nm. Specifically, the thickness of the pre-film layer may be 10 nm~20 nm, 20 nm~30 nm, 30 nm~40 nm, 40 nm~50 nm, 50 nm~60 nm, 60 nm~70 nm, 70 nm~80 nm, 80 nm~90 nm, or 90 nm~100 nm.

The substrate is selected from a silicon sheet. Other substrates that are insoluble in the developing agent may also be selected according to actual needs.

Furthermore, the present invention provides use of the above nanoparticle in the field of photoresist, in particular photoresists for electron beam, Mid-Ultra-Violet, Deep Ultra-Violet, and EUV. Regarding the mask, a transmission mask is adopted for the Deep Ultra-Violet and longer wavelength light sources, a reflection mask is adopted for the Extreme Ultra-Violet, and the electron beam is used for exposure according to the pattern set by the software.

### Example 1

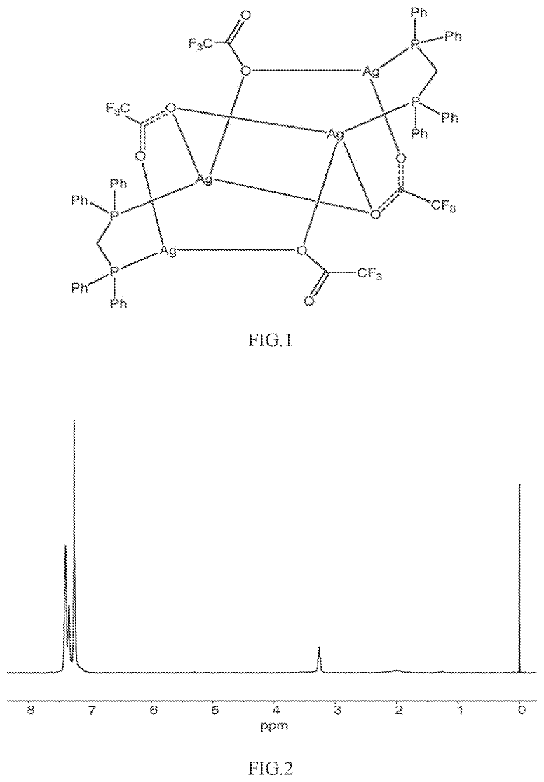

0.769 g bis(diphenylphosphino)methane was dissolved in 20 mL dichloromethane, 0.884 g silver trifluoroacetate was added thereto, the mixture was stirred for 12 h, filtered and evaporated, and the solvent was removed to obtain a white solid product. The product was recrystallized in dichloromethane, and dried in vacuum at room temperature, and a sample was taken for H NMR (hydrogen nuclear magnetic resonance) spectrum test (see FIG. 2, where δ 3.26 (CH₂), δ 7.26, 7.40 (C₆H₅)). The crystal had a structure as shown in FIG. 1, with the molecular formula of Ag₄(dppm)₂(CF₃COO)₄.

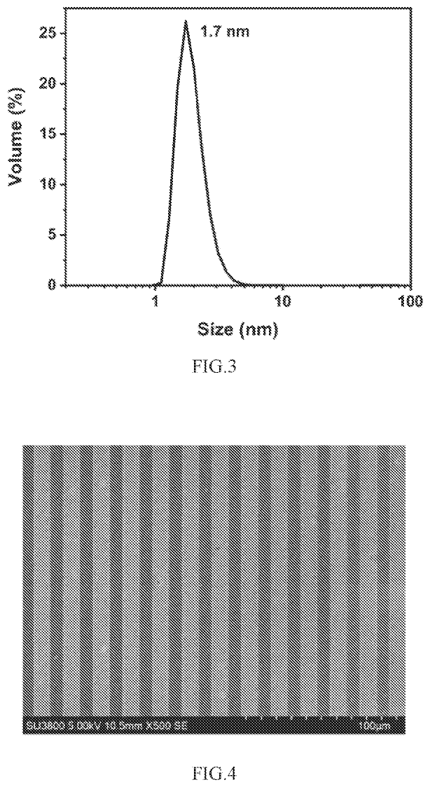

0.5 g Ag₄(dppm)₂(CF₃COO)₄and 0.05 g N-hydroxynaphthalimide trifluoromethanesulfonate were weighed and dissolved in 0.945 g propylene glycol monomethyl ether acetate, and the solution was filtered three times with a 0.22 μm filter head to obtain a photoresist composition. A dynamic light scattering particle size test was performed on the photoresist composition. The test results showed that the average particle size was 1.7 nm (see FIG. 3). The speed of the coater was set to 2000 rpm for 1 min, and the photoresist composition was spin-coated on the silicon wafer to form a uniform photoresist film. Then, the wafer was placed on a hot plate and heated at 80 °C for 1 min. The wafer was exposed by a light source of 254 nm wavelength mercury lamp with a dose of 1260 mJ/cm². M-xylene was used as a developing agent, and the wafer was developed for 10 s to obtain a line pattern with a half-pitch of 10 μm (see FIG. 4).

### Example 2

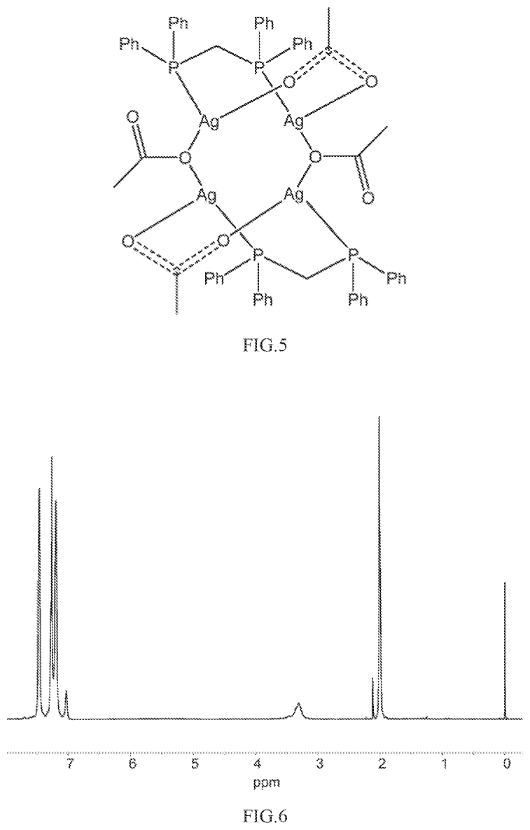

0.157 g of bis(diphenylphosphino)methane was dissolved in 16 mL dichloromethane, 0.136 g silver acetate was added thereto, and the mixture was stirred until a clear solution was obtained. The solution was filtered, concentrated, and cooled to produce a white precipitate. The precipitate was separated and recrystallized in dichloromethane/n-hexane, and the crystals were sampled for H NMR spectrum testing (see FIG. 6, H NMR spectrum δ 2.02 (CH₃), δ 3.31 (CH₂), δ 7.0-7.5 (C₆H₅)). The crystal had a structure as shown in FIG. 5, with the molecular formula of Ag₄(dppm)₂(CH₃COO)₄, and was dried in vacuum at room temperature.

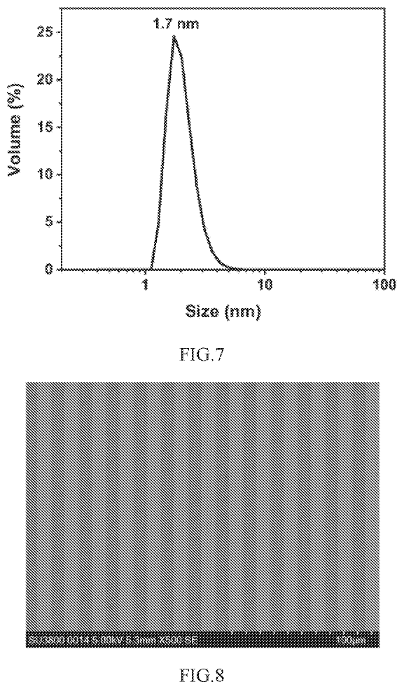

0.5 g Ag₄(dppm)₂(CH₃COO)₄ and 0.05 g N-hydroxynaphthaleneimide trifluoromethanesulfonate were weighted, and dissolved in 0.945 g propylene glycol monomethyl ether acetate, and the solution was filtered three times with a 0.22 μm filter. A dynamic light scattering particle size test was performed, and the test results showed that the average particle size was 1.7 nm (see FIG. 7). The speed of the coater was set to 2000 rpm for 1 min, and the photoresist composition was spin-coated on the silicon wafer to form a uniform photoresist film. Then, the wafer was placed on a hot plate and heated at 80 °C for 1 min. The wafer was exposed by a light source of 254 nm wavelength mercury lamp with a dose of 2000 mJ/cm². O-xylene was used as a developing agent, and the wafer was developed for 15 s to obtain a line pattern with a half-pitch of 10 μm (see FIG. 8).

### Example 3

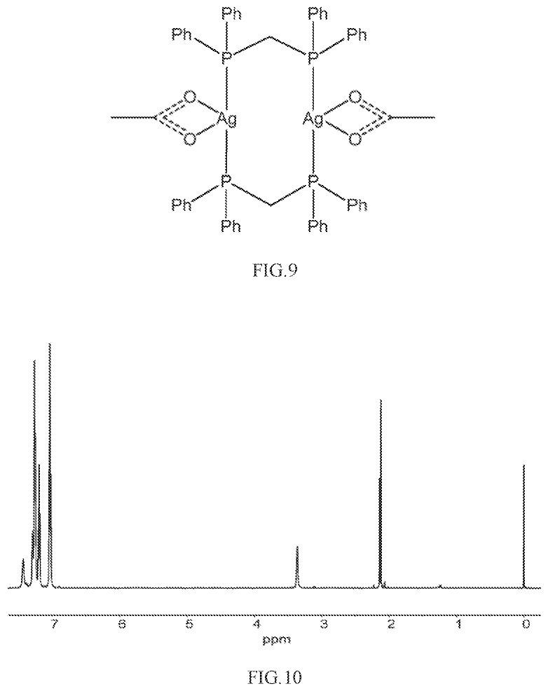

0.104 g Ag₄(dppm)₂(CH₃COO)₄ crystals were dissolved in 30 mL methanol, 0.056 g bis(diphenylphosphine)methane was added thereto, and the mixture was stirred until a clear solution was obtained. The solution was filtered, concentrated, and cooled to form a precipitate. The precipitate was separated and recrystallized in dichloromethane/n-hexane. The crystals were separated and sampled for H NMR testing (see FIG. 10, wherein H NMR spectrum δ 2.12 (CH₃), δ 3.36 (CH₂), δ6.95-7.45 (C₆H₅)). The crystal had a structure as shown in FIG. 9, with the molecular formula of Ag₂(dppm)₂(CH₃COO)₂, and was dried under vacuum at room temperature.

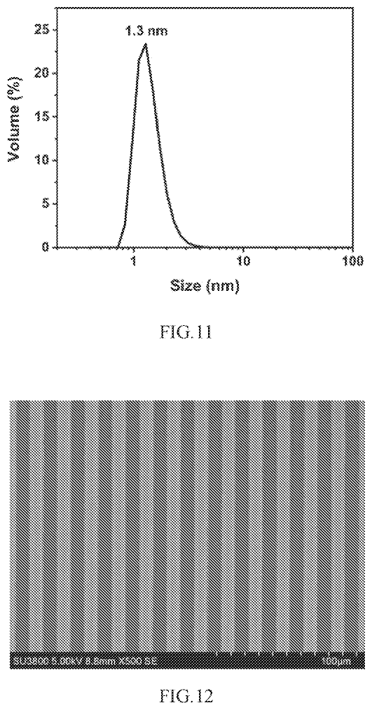

0.5 g Ag₂(dppm)₂(OAc)₂ and 0.05 g N-hydroxynaphthaleneimide trifluoromethanesulfonate were weighed and dissolved in 0.945 g propylene glycol monomethyl ether acetate. The solution was filtered three times with a 0.22 μm filter. The dynamic light scattering particle size test was performed and the test results showed that the average particle size was 1.3 nm (see FIG. 11). The speed of the coater was set to 2000 rpm for 1 min, and the photoresist composition was spin-coated on the silicon wafer to form a uniform photoresist film. Then, the wafer was placed on a hot plate and heated at 80 °C for 1 min. The wafer was exposed by a light source of 254 nm wavelength mercury lamp with a dose of 270 mJ/cm². M-xylene was used as a developing agent, and the wafer was developed for 30 s to obtain a line pattern with a half-pitch of 10 μm (see FIG. 12).

In summary, the present invention obtains a variety of effective nanoparticles and corresponding compositions, verifies the structures and good lithography performance under the conditions of Mid-Ultra-Violet and electron beam, which can achieve better lithography performance such as high resolution, high sensitivity and low line roughness.

1. An Ag-based organic coordination nanoparticle, with a general formula of [Agₘ(R)ₙ(Q)ₓ]_{y}, each of m, n, x and y is in the range of 1 to 4;
wherein R is selected from bis(diphenylphosphine)methane (dppm), bis(dicyclohexylphosphine)methane (abbreviated as dcpm), bis(diphenylamino)methane, N,N-bis(diphenylphosphine)amine (abbreviated as dppa), N,N,N′,N′-tetramethyldiaminomethane, N,N,N′,N′-tetraethyldiaminomethane; and
Q is selected from CH₃COO, C₂H₅COO, C₃H₇COO, i-C₃H₇COO, C₄H₉COO, C₆H₁₃COO, C₉H₁₉COO, C₆H₅COO, CF₃COO, C₂F₅COO, C₃F₇COO, i-C₃F₇COO, C₄F₉COO, C₆F₁₃COO, C₉F₁₉COO and C₆H₅COO.

2. The Ag-based organic coordination nanoparticle according to claim 1, wherein the specific structure of the nanoparticle comprising:
Ag₂(dppm)₂(CH₃COO)₂;
Ag₄(dppm)₂(CH₃COO)₄;
Ag₄(dppm)₂(CF₃COO)₄,
Ag₂(dppm)₂(C₂H₅COO)₂;
Ag₄(dppm)₂(C₂F₅COO)₄;
Ag₄(dppm)₂(C₄F₉COO)₄;
Ag₂(dcpm)₂(CH₃COO)₂;
Ag₄(dppa)₂(CH₃COO)₄.

3. The Ag-based organic coordination nanoparticle according to claim 1, wherein the size of the Ag-based organic coordination nanoparticle crystal is 1 nm to 4 nm.

4. The method for preparing the Ag-based organic coordination nanoparticle according to claim 1, comprising the following steps:
adding a silver salt and a first organic ligand to a sample bottle respectively, and adding an organic solvent thereto to dissolve them;
stirring the solution for a certain period under a certain temperature condition;
subjecting the solution to filtration, concentration, and cooling crystallization or evaporative crystallization; and
finally, performing recrystallization in an organic solvent to obtain the Ag-based organic coordination nanoparticle;
wherein the ratio of the silver salt to the first organic ligand is 1: (0.5~1).

5. The method for preparing the Ag-based organic coordination nanoparticle according to claim 4, wherein the organic solvent is any one or more selected from ethyl acetate, butyl acetate, propylene glycol monoethyl ether acetate, propylene glycol methyl ether acetate, 1-ethoxy-2-propanol, tetrahydrofuran, methanol, ethanol, propanol, dichloromethane, and trichloromethane.

6. The method for preparing the Ag-based organic coordination nanoparticle according to claim 4, wherein the stirring temperature is controlled at 0~120 °C.

7. A photoresist composition, comprising the Ag-based organic coordination nanoparticle according to claim 1, and further comprising a photoinitiator and an organic dispersing solvent,
wherein the photoinitiator makes up 0.1wt %-10wt % of the composition, and the Ag-based organic coordination nanoparticle makes up 1wt %-20wt % of the composition.

8. The photoresist composition according to claim 7, wherein the photoinitiator is any one or more selected from N-hydroxynaphthaleneimide trifluoromethanesulfonic acid, 1,4-aminonaphthalenesulfonic acid, 2-amino-5,7-naphthalene disulfonic acid, tert-butylphenyl iodonium perfluorooctanesulfonic acid, triphenylsulfonium perfluorobutanesulfonic acid, triphenylsulfonium perfluorobutyl and triphenylsulfonium trifluorosulfonic acid.

9. The photoresist composition according to claim 7, wherein the organic dispersing solvent is any one or more selected from ethyl acetate, butyl acetate, propylene glycol monoethyl ether acetate, propylene glycol methyl ether acetate, 1-methoxy-2-propanol, propylene glycol mono-n-propyl ether, propylene glycol butyl ether, 1-ethoxy-2-propanol, methanol, ethanol and propanol.

10. A method for patterning a photoresist containing an Ag-based organic coordination nanoparticle, comprising:
using the photoresist composition according to claim 7;
dripping the photoresist composition onto a substrate by spin-coating;
heating the substrate on a hot stage; then
exposing the substrate under electron beam or Mid-Ultra-Violet, Deep Ultra-Violet, or Extreme Ultra-Violet; and
developing the substrate with a developing agent;
wherein the spin-coating speed is 1000~6000 rpm, the heating temperature of the hot stage is controlled at 50~110 °C, the heating period is controlled at 30~900 s, and the exposure dose is 50~8000 mJ/cm²; the developing agent is any one or any mixture of more selected from decalin, tetralin, indene, indane, quinoline, 1-methylnaphthalene, toluene, o-xylene, m-xylene, ethyl acetate, butyl acetate, ethanol, n-propanol, isopropanol, n-butanol, n-hexane and cyclohexane, and the developing temperature is room temperature or from 20 °C to 50 °C, and the thickness of the pre-film layer after removing the organic dispersion solvent is 10 nm to 100 nm.

11. Use of the Ag-based organic coordination nanoparticles according to claim 1 in photoresists for electron beam, Mid-Ultra-Violet, Deep Ultra-Violet and/or Extreme Ultra-Violet.
